(19) United States
(12) Patent Application Publication
(10) Pub. No.: US 2024/0006216 A1
(43) Pub. Date: Jan. 4, 2024

(54) IMPROVED PLASMA RESISTANT COATINGS FOR ELECTROSTATIC CHUCKS

(71) Applicant: Oerlikon Surface Solutions AG, Pfäffikon, Pfäffikon (CH)

(72) Inventor: Matthew Paul KIRK, Lockport, NY (US)

(21) Appl. No.: 18/255,394

(22) PCT Filed: Dec. 2, 2021
(86) PCT No.: PCT/EP2021/084017

§ 371 Date: Jun. 1, 2023

Related U.S. Application Data
(60) Provisional application No. 62/120,497, filed on Feb. 25, 2015.

(51) Int. Cl. H01L 21/683; H01J 37/32; C23C 14/02; C23C 14/35; C23C 16/02

(52) U.S. Cl. CPC H01L 21/6833; H01J 37/32697; H01J 37/32715; C23C 14/025; H01J 37/32495; C23C 14/35; C23C 16/0281; H01J 2237/3341

(57) ABSTRACT

A device to be used within a plasma etching chamber for the manufacturing of semiconductor components, including providing a body forming the substrate of the device, applying a first coating on the surface of the body, wherein the first coating includes a metal and/or a metal alloy thin film coating layer in order to form a metal coated body, applying a second coating on the metal coated body, wherein the second coating includes a ceramic coating layer, wherein the second coating at least partially overlaps with the first coating.

The present invention relates to a method for producing a device to be used within a plasma etching chamber for the manufacturing of semiconductor components as well as to a device to be used within a plasma etching chamber for the manufacturing of semiconductor components, preferably produced by such a method.

Devices like electrostatic chucks are commonly used in semiconductor technology. An electrostatic chuck (E-chuck) is often coated with a layer system comprising ceramic phase coatings (oxides, nitrides, borides, carbides, oxynitrides, . . . ) which are commonly used for semiconductor device manufacturing. Such E-chucks are used in semiconductor etch chambers and they need to be coated with coatings resistant to etching by ion bombardment and halogen gas in order to protect the E-chuck exposed to the etching plasma.

### STATE OF THE ART

The current state-of-the-art for constructing plasma resistant E-chucks is a method to fabricate a minimum contact area (MCA) mesa structure that for example a silicon wafer rests upon during processing. Fabrication of this mesa MCA structure utilizes a positive hard mask (it translates its pattern into ‘high’ points of the MCA structure) and a subtractive ablation process (often a blasting operation) in order to remove an adequate amount of material to leave the mesas in the desired height. This process has certain drawbacks with respect to particulate contamination, resulting in semiconductor die yield loss. Other drawbacks include the limited ability to refurbish and restore the E-chucks after some production usage. The state-of-the-art refurbishment includes a grinding/polishing step that removes a certain amount of the base ceramic material and the re-creation of the MCA pattern that has been mentioned before. Due to the importance of the dielectric properties of the base ceramic, the change of the thickness can have a deleterious effect on the electrostatic performance of the E-chuck, limiting the number of times it can be refurbished due to performance degradation.

However according to a new methodology MCA pattern is created with a reverse mask in an additive process via thin film deposition which obviates the aforementioned issues.

Such thin film deposited coatings typically consist of oxides, oxynitrides and oxyfluorides, which are applied by various methods including PVD and spray technologies. Even though these coatings have a low etching rate, they get thinner with usage or in some cases mechanical wear and have to be replaced at some point. Replacement of the coating may also be required if damage occurs during handling (ex. by scratches). This is motivated by the costs of the typical components and in some cases by the need to maintain dielectric properties if the coating gets too thin (i.e. for the function of electrostatic chucks, E-chucks). There is therefore the need for etch-resistant coatings which are easy to refurbish.

Mechanical removal of the coating by methods like grit blasting or lapping are not practical in some cases or have the drawback of damaging the components each time they are applied. This is especially the case for patterned surfaces like the mesa structures on E-chucks as mentioned above. Therefore, selectively removing the coating in a conformal manner by a chemical or electro-chemical method would be greatly advantageous. However, these methods are unfortunately not very efficient for etch-resistant coatings, which are by design inert towards most chemicals. This challenge is even greater if the etch-resistant coating is applied onto a substrate of a similar chemical nature (i.e. Al₂O₃/AlON coating on the Al₂O₃/AlON surface of an E-chuck).

The U.S. Pat. No. 10,497,598B2 discloses an electrostatic chuck comprising a ceramic structural element, at least one electrode disposed on the ceramic structural element and a surface dielectric layer disposed over the at least one electrode. The surface dielectric layer comprises an insulating layer of amorphous alumina of a thickness of less than 5 microns disposed directly over the at least one electrode, and a stack of dielectric layers disposed over the insulator comprising at least one dielectric layer including aluminum oxynitride and at least one dielectric layer including at least one silicon oxide and silicon oxynitride.

The U.S. Pat. No. 9,761,417B2 discloses a bilayer coating made of plasma-resistant layer of AlON overlying directly onto the substrate to protect and having a thickness from about 1 micron to about 10 microns thick, and an outermost plasma-resistant layer of yttria coating that is also from about 1 micron to about 10 microns thick immediately overlying the AlON layer. The plasma-resistant layer for protection is directly deposited onto the substrate being a component in a semiconductor manufacturing system and can be quartz, alumina, aluminum, steels, metals, or alloys. Both AlON and yttria layer are deposited on the substrate to protect it from plasma exposure during semiconductor manufacturing by pulsed reactive physical vapor deposition.

The U.S. Pat. No. 10,020,218B2 discloses an electrostatic chuck comprising a ceramic body made of AlN or Al₂O₃ comprising an embedded electrode; a first ceramic coating deposited directly onto a surface of the ceramic body, a second ceramic coating on the first ceramic coating which comprises a material from the group consisting of Al₂O₃, AlN, Y₂O₃, Y₂Al₅O₁₂ (YAG) and AlON and having a thickness of about 5-30 μm; and a plurality of elliptical mesas on the second ceramic coating having a diameter of about 0.5-2.0 mm and a thickness of about 2-20 microns.

The U.S. Pat. No. 8,206,829B2 discloses a plasma resistant coating and methods of forming such coatings on a plasma chamber component such as electrostatic chuck, wherein the plasma resistant coating comprises a crystalline ceramic non-native to the substrate and formed in a manner to include at least one of an oxide, nitride, boride, carbide, or halide of Yttrium, iridium (Ir), rhodium (Rh), or lanthanoid, such as Erbium (Er) and a porosity below 1%. The plasma resistant coating is deposited over at least a portion of the substrate via an intermediate layer disposed between the substrate and the plasma resistant coating, wherein the intermediate layer comprises an oxide, nitride, or carbide of an element other than that of the primary constituent in the plasma resistant coating.

The U.S. Pat. No. 9,633,884B2 discloses a plasma-resistant coating covering an electrostatic chuck assembly for a plasma processing chamber consisting of a mixture of Y₂O₃/Al₂O₃ or YF₃/Al₂O₃ deposited by plasma-enhanced physical vapor deposition.

The authors also disclose an undercoat layer provided in between the E-chuck to protect and the plasma-resistant coating which comprises at least one of Y₂O₃ and Al₂O₃ and formed using standard plasma spray.

The U.S. Pat. No. 7,732,056B2 discloses a method of providing a plasma-resistant coating on a surface of an aluminum component which comprises anodizing the surface of the aluminum component to form an anodized aluminum oxide layer and a sputtered layer comprising aluminum oxide deposited directly onto the anodized aluminum oxide layer.

The US20190067069A1 discloses an electrostatic chuck comprising an electrode in a ceramic base, and a surface layer wherein the surface layer comprises a plurality of protrusions, the protrusions comprising a composition whose morphology is columnar or granular. Materials forming the protrusions can be made entirely of physical deposited aluminum oxynitride (AlON) or may be a coating of aluminum oxynitride overtop of an underlying ceramic like alumina. Other examples of materials that can be used for protrusions can include yttria (Y₂O₃), yttrium aluminum garnet (YAG), alumina (Al₂O₃), or aluminum oxynitride.

All the above-mentioned patents disclose a solution based on the direct deposition of a functional ceramic thin film onto the surface of the base ceramic. The reliability and performance of the E-chucks are therefore intrinsically linked on the resilience of the ceramic layer to adhere well on a base ceramic component. However, it is well-known that ceramic coatings are easily prone to cracking during mechanical solicitations due to their brittle mechanical behavior. The weak and unstable coating integrity can result in a premature coating failures and even catastrophic film delamination, hampering the lifetime time and performance of the E-chucks.

U.S. Pat. No. 7,077,918 describes a method for stripping a coating off a ceramic or metallic work piece. In order to facilitate the stripping at least a first chromous and aluminiferous coat is applied directly on the work piece. On this coat deposited is a functional layer made of nitride of AlCr known for its large pored structure. Stripping is then performed with a permanganate solution. The solution does not attack the nitride of AlCr but through its large pores the AlCr layer is attacked as expected. However, by the use of ceramic layers with finer pores and better protection compared to plasma etching processes it is not expected to destroy a metallic layer located under the ceramic layer.

### OBJECTIVE OF THE PRESENT INVENTION

It is an object of the present invention to alleviate or to overcome one or more difficulties related to the prior art. In particular, it is an object of the present invention to provide a method for producing a device as well as a device, which has a high surface resistance in plasma etching processes, can be easily and quickly surface renewed as required and offers great flexibility with regard to the selection of coating materials.

### DESCRIPTION OF THE PRESENT INVENTION

In order to overcome these problems, a method for producing a device to be used within a plasma etching chamber for the manufacturing of semiconductor components has been invented.

Thus, in a first aspect of the present invention disclosed is a method for producing a device to be used within a plasma etching chamber for the manufacturing of semiconductor components comprising:
providing a body forming the substrate of the device,
applying a first coating on the surface of the body, wherein the first coating comprises a metal and/or a metal alloy thin film coating layer in order to form a metal coated body,
applying a second coating on the metal coated body, wherein the second coating comprises a ceramic coating layer, wherein the second coating at least partially overlaps with the first coating.

Hereby, the device may preferably be designed as an electrostatic chuck. Moreover, the first and/or second coating may be applied at least partially on the surface of the body of the device. The term that the second coating at least partially overlaps with the first coating may preferably be understood in that the second coating may be at least partially applied over the first coating which includes a direct connection as well as an indirect connection between the first and the second coating.

In another example of the first aspect, the method may comprise manufacturing the body, wherein the manufacturing may comprise uncoating the body, preferably by polishing and cleaning the surface of the body, wherein in particular plasma methods and/or ion bombardment may be used for cleaning and/or activating the surface. Alternatively or cumulatively, the manufacturing may comprise treating the body with an alkaline or oxidizing substance to dissolve existing coatings from the surface of the body.

In another example of the first aspect, an intermediate coating comprising metallic and ceramic components may be applied between the first coating and the second coating, wherein the intermediate coating may be applied preferably by using a controlled feed of reactive gases forming the ceramic components while continuously decreasing the addition of metallic components in order to create a gradient of the metallic component within the intermediate coating starting with a higher amount of the metallic compound at the interface to the first coating and finishing with a lower amount of the metallic compound at the interface to the second coating, wherein in particular the feed of the reactive gases forming the ceramic components and/or the addition of the metallic compound may be variated at least partially stepwise and/or at least partially continuously. In other words the atomic composition may change with depth from at least almost metallic near the interface to the first layer to at least almost ceramic near the interface to the second coating, wherein such change may be at least partially stepwise and/or at least being partially continuous, thereby forming a gradient.

Thus, in this invention, a special coating architecture using a dedicated base or intermediate layer is proposed in order to solve the problem of the invention. The nature of this interlayer is chosen to allow for an efficient de-coating with the wet chemical method. Examples of wet chemical methods may involve i.e. alkaline or oxidative solutions. The solution dissolves or oxidizes the interlayer, resulting in a “lift-off” or removal of the etch-resistant layer.

The interlayer also has the function of promoting adhesion of the etch-resistant layer to the surface of the component.

Thus, disclosed here is also a method for increasing the adhesion strength of vacuum deposited ceramic coatings to different substrate materials for E-chucks. These materials may include aluminium, stainless steel and various types of ceramics like Al₂O₃, quartz, Al₂O₃/AlON and ALN. According to the present invention this may be done by depositing a thin, pure metallic layer followed by a gradual transition going from pure metal phase to a ceramic phase coating. The top functional layer through the improved adhesion is able to provide a more robust surface for aggressive applications then weaker bonded homogeneous films that do not have such an interlayer structure.

The intention of the present invention is thereby to solve the problem of inadequate adhesion and easy de-coating when refurbishing of homogeneous ceramic films to base materials. In order to improve the adhesion strength and facilitate the de-coating of the functional etch-resistant coating, the use of a metallic thin film layer or layer system is proposed before the homogeneous ceramic layer is deposited.

According to a preferred embodiment a gradual transition from a metallic based coating to a ceramic based coating may be realized. Depending on the method of deposition, process stability and repeatability are improved as well through this gradual transition from a metal to a ceramic based coating. Instead of abrupt changes in the process conditions a slow transition may be employed to make the coating more structurally robust and repeatable.

As turned out surprisingly even with the quite dense ceramic layers as used for E-chucks the intermediate metal layer facilitates the stripping method. One possible explanation could be that the ceramic layer may comprise pores which are however small enough that the plasma cannot enter, however are big enough that the stripping solution enters and attacks the underlying metal based coating.

Based on this explanation and according to a preferred embodiment of the present invention the body forming the device to be used in an etching chamber may be micro- and or nanostructured in order to even further improve the access of the stripping agent to the metallic coating on the body of the device. This may be done by structuring the uncoated body. The upper layers of the thin film coatings will then only to a certain extend or to a certain amount be in contact with lower areas of the structure.

On the other side, if a solvent agent may easily enter into the grooves of the body, thereby dissolving effectively the metal coating and as a consequence a lift off effect happens and the ceramic layer is removed as well.

Based on this, in a further example of the first aspect the method may comprise a step of micro- and/or nanostructuring the device, wherein the structures being introduced by micro- and/or nanostructuring preferably may be made in form of grating structures, in particular introduced into the body of the device.

As just explained (and not limited to the example as given above), the ease of coating removal for component level refurbishment is made easier by the employment of this adhesion layer structure. Chemical stripping methods can be used to remove the ceramic coatings rather easily due to the chemical attack of the metal-based layer. This works simply by undercutting of the ceramic film which results in film detachment from the substrate surface. In the case of homogeneous ceramic coatings with no metal layers, there is no such layer for the chemicals to attack. Stripping of these types of coatings is therefore much more difficult.

One specific area where this improved stripping may be applied is the removal of deposited ceramic coatings from hard shadow masking. For example, if this masking is being used to deposit features onto electrostatic chucks the masking will need to be cleaned periodically. This routine stripping of the mask is needed to prevent possible flaking from thick coating build up which can lead to particles in the coating. If the masking is of a ceramic material like Al₂O₃ the use of the metallic layer makes the stripping of the masks more efficient and repeatable.

In order to ensure an exact and targeted layer build-up, vacuum coating methods may be used for applying the first coating and/or the second coating and/or the intermediate coating, wherein preferably CVD- or PVD-techniques, in particular magnetron sputtering techniques may be used.

With respect to the layer build-up, as the first coating a pure metal layer and/or a pure metal alloy may be applied to the surface of the body, wherein the metal layer and/or the metal alloy may comprise at least one of the following metals: Al, V, Ti, Hf, Y, Er, Sc, Ce, La.

Furthermore, with respect to the layer build-up as the second coating a pure ceramic layer may be applied to the surface of the body, wherein the ceramic layer preferably may comprise at least one of the following: oxides, nitrides, oxynitrides, silicates, fluorides, carbides, oxyfluorides, wherein the reactive gases to form the ceramics in particular may be fed slowly and ramped.

In a second aspect of the present invention disclosed is a device to be used within a plasma etching chamber for the manufacturing of semiconductor components, preferably produced by a method according to one of the previous claims, comprising a body forming the substrate of the device, a first coating applied on the surface of the body, wherein the first coating comprises a metal and/or metal alloy thin film coating layer, a second coating on the metal coated body, wherein the second coating comprises a ceramic coating layer, wherein the second coating at least partially overlaps with the first coating. The body forming the substrate of the device may include aluminium, stainless steel and/or various types of ceramics like Al₂O₃, quartz, Al₂O₃/AlON or ALN.

In another example of the second aspect, the device may further include an intermediate coating located between the first and the second coating, wherein the intermediate coating comprises metallic and ceramic components, which may be preferably inhomogeneously distributed within the layer.

With respect to the intermediate coating, the metallic portion within the intermediate coating may continuously decrease starting from the interface between the intermediate coating and the first coating to the interface between the intermediate coating and the second coating and wherein at the same time the ceramic portion within the layer may continuously increase starting from the interface between the intermediate coating and the first coating to the interface between the intermediate coating and the second coating, wherein the ratio of the metallic component and the ceramic component to each other preferably may change at least partially stepwise and/or at least continuously.

In order to guarantee a high surface resistance in plasma etching processes combined with the ability to be easily and quickly surface renewed, the second coating and if given the intermediate coating may comprise pores, wherein the pores preferably may have a different pore diameter at a pore inlet and a pore outlet, wherein the diameter of the pores at the pore inlet adjacent to the second coating may be in particular smaller than at the pore outlet adjacent to the first coating.

In particular the coatings including the pores of the device may be designed that plasma in a plasma etching process cannot enter the second coating, however the coatings may be designed, in particular that pores being large enough to allow a stripping agent to enter the coatings and allow to dissolve the first coating.

In a further example of the second aspect the device may comprise micro- and/or nanostructured parts, wherein the micro- and/or nanostructured parts preferably may be in form of grid structures, in particular introduced into the body of the device.

With respect to the micro- and/or nanostructured parts, the grid structures may comprise protrusions and apertures disposed between two neighbouring protrusions, wherein the apertures preferably may comprise a constriction disposed between two neighbouring protrusions adjacent to the second coating, wherein the diameter of the apertures in particular may increase continuously from the constriction to the bottom of the grid within the apertures.

Hereby, the ceramic top layer preferably may not extend to the bottom of the grid within the apertures, wherein the bottom of the grid may only be coated with a metallic coating.

With respect to the layer build-up the first coating may be a pure metal and/or metal alloy thin film, preferably comprising at least one of the following metals: Al, V, Ti, Hf Y, Er, Sc, Ce, La.

With respect to the layer build-up the second coating may be a pure ceramic layer, preferably comprising at least one of the following: oxides, nitrides, oxynitrides, silicates, fluorides, carbides, oxyfluorides.

Hereby, the micro- and/or nanostructured parts may be designed in the form of a periodic grid structure, wherein the distances between two adjacent protrusions may preferably be at least 200 nm in width, in particular at least 400 nm in width. According to a particularly preferred embodiment the distances between two adjacent protrusions may also be more than 500 nm in width.

In another example of the second aspect, the device may be inhomogeneously coated along its surface, wherein the layer thickness of the first and/or second coating and/or the intermediate coating may be thinner at some points than at other points at the surface.

Preferably in an embodiment of the device with a grid structure, the coating (first and/or second coating and/or the intermediate coating) may be distributed inhomogeneously along its surface, wherein the coating (first and/or second coating and/or the intermediate coating) preferably being thicker on the upper side of the grid at the protrusions than the coating in the region of the bottom within the apertures.

According to a preferred embodiment the device may be an electrostatic chuck or a hard shadow masking device.

The invention can be used with electrostatic chucks; however, the concepts of the invention are intended to have a wider applicability both within the semiconductor processing industry and within other industries as well.

The utilization of a metallic adhesion promoting layer followed by a transition layer to a homogeneous ceramic layer was found to produce the best adhesion results. This layer structure also improves the ease of chemical stripping of the coating as needed.

The invention will now be described in more details based on examples and with the help of figures.

### DESCRIPTION OF THE FIGURES

FIG. 1: Shows a cross section of the current state of the art solution

(1) Substrate

(2) Ceramic based monolayer,

FIG. 2: Shows a cross section of an embodiment of the present invention and shows the layers made to create the film stack

(1) Substrate

(2) Pure metal layer

(3) Transition layer (pure metal to ceramic)

(4) Ceramic based layer,

FIG. 3: Shows a scratch test on ALON monolayer coating directly coated onto the substrate. The substrate material is Al₂O₃, the coating thickness is ˜21 μm. As the test revealed the Lc₂ failure is detected at 34N load,

FIG. 4: Shows a scratch test on a coating with a pure Aluminium adhesion layer and transition to the ALON functional layer according to one embodiment of the present invention. The substrate material is Al₂O₃ the coating thickness is ˜23 μm. As the test revealed the Lc₂ failure is detected at 50N load,

FIG. 5: Shows an example of a coated periodical rectangular grating structure introduced into the body of the device,

FIG. 6: Shows a sample with an AlON film directly coated on an Al₂O₃ substrate before stripping,

FIG. 7: Shows the sample with the AlON film according to FIG. 6 after stripping,

FIG. 8: Shows a sample with an AlON film coated on a metallic interlayer which is directly coated on the substrate before stripping,

FIG. 9: Shows the sample with the AlON film coated on the metallic interlayer according to FIG. 8 after stripping.

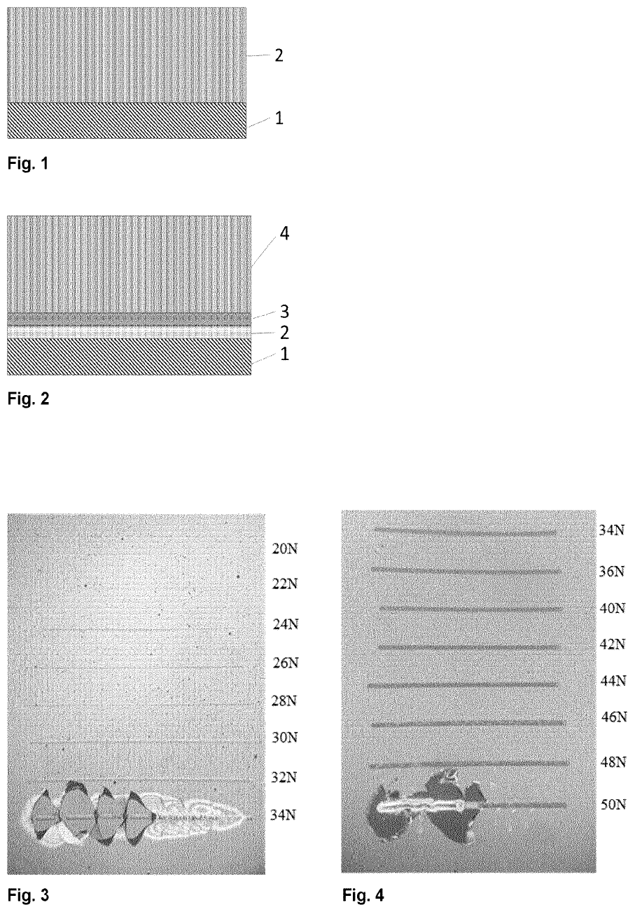

### DETAILED DESCRIPTION OF THE INVENTIVE SOLUTION

In order to create an improved adhesion layer structure for the ceramic coatings, a vacuum deposition source is used to deposit a pure metal layer onto a clean substrate surface of an E-chuck. The coatings may include but are not limited to oxides, nitrides, borides, carbides, oxyfluorides as well as classes of materials such as Al, V Ti Zr, Hf Y, Er, Sc, Ce, La as well as AlON. The substrate surface can be cleaned or activated by plasma cleaning or ion bombardment prior to the deposition of the metal. After a certain thickness of the pure metal layer is deposited, reactive gasses (such as O₂, and/or N₂, and/or Fluorine containing gasses) are introduced slowly and ramped over a period of minutes until a fully stoichiometric ceramic coating is realized. At this point the deposition is left to continue for some time during which the functional layer is deposited.

A more detailed example is given below.

### EXAMPLE

In the case of this example, an ALON (Aluminum Oxynitride) coating was deposited using magnetron reactive sputtering. A metal-based adhesion layer and transition were created before the functional ALON was deposited. The following steps were taken to create this film:
1. The polished (4 μm Ra) Aluminum Oxide surface of an E-chuck was solvent cleaned and the E-chuck loaded onto a 2-axis of rotation planetary system inside a stainless-steel deposition system.
2. The chamber was evacuated to the low 10E-05 mbar range.
3. Argon plasma etching of substrates was done for 7 min. duration using a DC filament discharge and pulsed DC substrate biasing.
4. The operating pressure was then adjusted to 4.5E⁻³ mbar with turbo pump speed regulation along with the Argon flow regulated to 180 sccm.
5. Pulsed DC power was then delivered to a balanced ∅8″ circular planar Aluminum target (99% purity) starting at a 50% power setting and then ramping to 6 kW in one minute.
6. Sputtering at 6 kW was continued for a 10 min. duration in order to create the pure Aluminum adhesion layer.
7. The operating cathode voltage of the sputtering target was then noted to be ˜565V in the pure metallic mode.
8. A closed loop control of reactive gasses O₂ and N₂ was then used to create the transition from pure Aluminum to Aluminum oxynitride using a control of reactive process by discharge voltage regulation device. The software control of this device allows the user to program a ramping function while utilizing a master/slave control of the reactive gasses. In this case the N₂ channel is the master and the O₂ is the slave. The ratio of O to N was set to a ratio of 3.5:6.5. The reactive gasses are then ramped at this set ratio slowly over a period of 20 min. so that the cathode voltage decreases steadily from 565V (pure metal film) to a final set point of 400V (fully oxy-nitrided film). At this point the O/N ratio is still fixed and minor adjustments in gas flow is achieved by the regulation device to maintain the 400V operating setpoint on the sputtering cathode for the duration of the deposition.
9. The conditions are then held at constant until the desired thickness is reached for the functional top layer of the coating.

The resulting coating was comprised of a pure Aluminum layer of ˜0.8 microns thickness, a transitional gradient layer of ˜0.8 micron thickness and a functional top layer of ˜21 microns. The adhesion strength was compared between the two coatings using a 200μ radius conical diamond tip scratch tester. 3 mm length scratches were done in 2N load increments until Lc2 adhesive failure was achieved (FIG. 3,4). Compared to a monolayer ALON coating deposited under the same conditions with no adhesion layers the adhesion values were improved substantially with the use of this interlayer structure.

The pure metallic layer improves the bonding of the upper layers to the substrate material. The transition from metal to the ceramic layer provides good bonding between the metal layer and the upper function layer. The transitional layer acts as an intermediate layer with a hardness and Young's modulus that lies between the softer pure metal layer and the harder functional layer. This structure provides for a more robust coating that is better able to withstand any force or stresses that might occur on the functional layer.

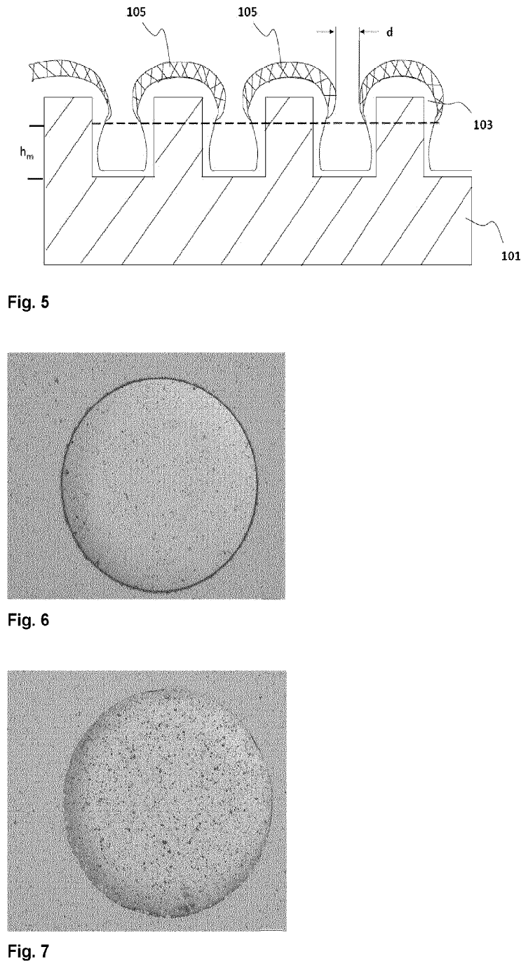

FIG. 5 shows an example of a coated periodical rectangular grating structure introduced into the body 101 of the device. As can be seen from FIG. 5, the structured body 101, comprises a periodical rectangular grating structure (with a grating period of 500 nm and a fill factor of 0.5). The body is coated with a metallic coating 103. Because auf shadowing effects the coating thickness on top of the grating is thicker as compared to the metallic coating in the area of the grooves. As FIG. 5 shows, the openings of the gratings are narrowed due to the coating. This has the effect that the ceramic overcoat 105 (shown in FIG. 5 as crossed area) is not reaching the bottom of the grooves. In effect in depth region indicated as hₘ in the FIG. 5 only the metallic coating exists. The openings to the grooves are narrowed down to “d”. This prevents the etching plasma from entering into the grooves and the ceramic coating 105 will fully protect the device. As an additional effect, due to the structuring the adhesion of the coating to the structured body 101 is increased.

Chemical removal of the coating is also easier in comparison to homogenous type ceramic films covered in the prior art. This is primarily due to the ability of the stripping chemical to attack the metallic adhesion layer through the coating thus causing coating detachment.

In order to demonstrate the positive effect of stripping when a metallic interlayer is applied, two Al₂O₃ substrates were coated with a circular shaped AlON ceramic film. On one substrate, a thick AlON ceramic film was directly deposited onto the ceramic substrate Al₂O₃ while, on the other sample, a metallic layer was first deposited onto the sample, followed by a transitional gradient layer and finally the deposition of the thick ceramic AlON film, as previously described.

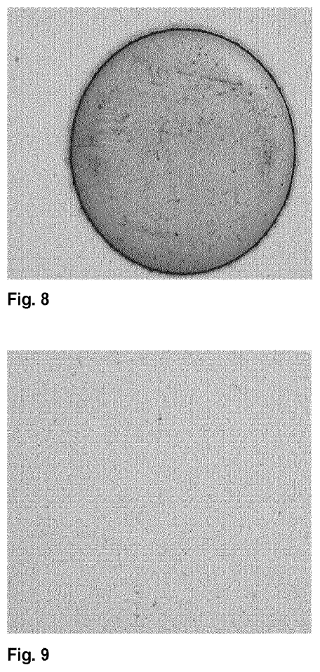

After deposition of the coating, it was tried to strip the ceramic films with the help of 10% NaOH alkaline solution at room temperature for 90 minutes. FIG. 6 shows the sample with the AlON film directly coated on the substrate before stripping and FIG. 7 shows the sample after stripping. As can be seen in FIG. 7, the circular ceramic film is attacked, however not completely removed. FIG. 8 shows the sample with the AlON film coated on the metallic interlayer and FIG. 9 shows the sample after stripping. As can be seen, the circular ceramic film is completely removed. Very interestingly, no damages (pitting, cracks) were observed at the surface of the freshly uncoated Al₂O₃ substrate after stripping.

Other solutions could be used for the stripping. For example a KOH solution is expected to do a good job as well.

What is claimed is:

1. Method for producing a device to be used within a plasma etching chamber for the manufacturing of semiconductor components, comprising:
providing a body forming the substrate of the device,
applying a first coating on the surface of the body, wherein the first coating comprises a metal and/or a metal alloy thin film coating layer in order to form a metal coated body,
applying a second coating on the metal coated body, wherein the second coating comprises a ceramic coating layer, wherein the second coating at least partially overlaps with the first coating.

2. Method according to claim 1, wherein the method comprises manufacturing the body, wherein the manufacturing comprises uncoating the body, preferably by polishing and cleaning the surface of the body, wherein in particular plasma methods and/or ion bombardment is used for cleaning and/or activating the surface.

3. Method according to claim 1, wherein the manufacturing comprises treating the body with an alkaline or oxidizing substance to dissolve existing coatings from the surface of the body.

4. Method according to claim 1, wherein an intermediate coating comprising metallic and ceramic components is applied between the first coating and the second coating, wherein the intermediate coating is applied preferably by using a controlled feed of reactive gases forming the ceramic components while continuously decreasing the addition of metallic components in order to create a gradient of the metallic component within the intermediate coating starting with a higher amount of the metallic compound at the interface to the first coating and finishing with a lower amount of the metallic compound at the interface to the second coating, wherein in particular the feed of the reactive gases forming the ceramic components and/or the addition of the metallic compound is variated at least partially stepwise and/or at least partially continuously.

5. Method according to claim 1, wherein the method comprises a step of micro- and/or nanostructuring the device, wherein the structures being introduced by micro- and/or nanostructuring preferably are made in form of grating structures, in particular introduced into the body of the device.

6. Method according to claim 1, wherein vacuum coating methods are used for applying the first coating and/or the second coating and/or the intermediate coating, wherein preferably CVD- or PVD-techniques, in particular magnetron sputtering techniques are used.

7. Method according to claim 1, wherein as the first coating a pure metal layer and/or a pure metal alloy is applied to the surface of the body, wherein the metal layer and/or the metal alloy comprises at least one of the following metals: Al, V, Ti, Hf, Y, Er, Sc, Ce, La.

8. Method according to claim 1, wherein as the second coating a pure ceramic layer is applied to the surface of the body, wherein the ceramic layer preferably comprises at least one of the following: oxides, nitrides, oxynitrides, silicates, fluorides, carbides, oxyfluorides, wherein the reactive gases to form the ceramics in particular are fed slowly and ramped.

9. Device to be used within a plasma etching chamber for the manufacturing of semiconductor components, comprising:
a body forming the substrate of the device,
a first coating applied on the surface of the body, wherein the first coating comprises a metal and/or metal alloy thin film coating layer,
a second coating on the metal coated body, wherein the second coating comprises a ceramic coating layer, wherein the second coating at least partially overlaps with the first coating.

10. Device according to claim 9, wherein the device comprises additionally an intermediate coating, wherein the intermediate coating comprises metallic and ceramic components, which are preferably inhomogeneously distributed within the layer.

11. Device according to claim 10, wherein the metallic portion within the intermediate coating continuously decreases starting from the interface between the intermediate coating and the first coating to the interface between the intermediate coating and the second coating and wherein at the same time the ceramic portion within the layer continuously increases starting from the interface between the intermediate coating and the first coating to the interface between the intermediate coating and the second coating, wherein the ratio of the metallic component and the ceramic component to each other preferably changes at least partially stepwise and/or at least continuously.

12. Device according to claim 9, wherein the second coating and if given the intermediate coating comprises pores, wherein the pores preferably have a different pore diameter at a pore inlet and a pore outlet, wherein the diameter of the pores at the pore inlet adjacent to the second coating is in particular smaller than at the pore outlet adjacent to the first coating.

13. Device, according to claim 9, wherein the device comprises micro- and/or nanostructured parts, wherein the micro- and/or nanostructured parts preferably are made in form of grid structures, in particular introduced into the body of the device.

14. The device of claim 13, wherein the grid structures comprise protrusions and apertures disposed between two neighbouring protrusions, wherein the apertures preferably comprising a constriction disposed between two neighbouring protrusions adjacent to the second coating, wherein the diameter of the apertures in particular increases continuously from the constriction to the bottom of the grid within the apertures.

15. Device according to claim 13, wherein the ceramic top layer is applied partially on the surface of the body, wherein the ceramic top layer preferably does not extend to the bottom of the grid within the apertures, wherein the bottom of the grid is only coated with a metallic coating.

16. Device according to claim 9, wherein the first coating is a pure metal and/or metal alloy thin film, preferably comprising at least one of the following metals: Al, V, Ti, Hf, Y, Er, Sc, Ce, La.

17. Device according to claim 9, wherein the second coating is a pure ceramic layer, preferably comprising at least one of the following: oxides, nitrides, oxynitrides, silicates, fluorides, carbides, oxyfluorides.

18. Device according to claim 9, wherein the micro- and/or nanostructured parts are designed in the form of a periodic grid structure, wherein the distances between two adjacent protrusions are preferably at least 200 nm in width, in particular at least 400 nm in width.

19. Device according to claim 9, wherein the device is inhomogeneously coated along its surface, wherein the layer thickness of the first and/or second coating and/or the intermediate coating being thinner at some points than at other points at the surface.

20. Device according to claim 9, wherein the device is an electrostatic chuck or a hard shadow masking device.
